(19) United States
(12) Patent Application Publication
(10) Pub. No.: US 2006/0056263 A1
(43) Pub. Date: Mar. 16, 2006

(54) Semiconductor memory device and electronic apparatus

(75) Inventors: Eitaro Otsuka, Fujimi-cho (JP); Masaya Uehara, Chino-shi (JP); Shuhei Nakayama, Chino-shi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/201,167

(22) Filed: Aug. 11, 2005

(30) Foreign Application Priority Data
Sep. 15, 2004 (JP) 2004-267722

(51) Int. Cl. G11C 8/00

(52) U.S. Cl. 365/230.03

(57) ABSTRACT

A semiconductor memory device includes a plurality of banks including memory cell arrays in which dynamic type memory cells are arranged in a matrix, according to an input address and an input control command in synchronization with a clock signal, the memory cell corresponding to the input address being accessed in response to the input control command; wherein the input address is set as an X address for selecting a word line in the memory cell array, a Y address for selecting a data line pair in the memory cell array, and a bank address for selecting a bank, the bank address being placed in lower bits than the X address; and wherein, in burst operations that correspond to a sequence of addresses containing the input address as a leading address and consecutively perform access corresponding to the input control command to a plurality of memory cells arranged over the plurality of banks, in order for a sequence of memory cells included in one bank among the plurality of memory cells to be accessed, a word line corresponding to the sequence of memory cells is activated while a word line corresponding to a sequence of memory cells included in another bank to be accessed subsequent to access to the sequence of memory cells included in the one bank is activated in advance, and access to the sequence of memory cells included in the one bank and access to the sequence of memory cells included in the another bank are consecutively performed in synchronization with the clock signal.

### BACKGROUND OF THE INVENTION

1. Technical Field

This invention relates to access control in burst mode in a semiconductor memory device with a memory cell array in which dynamic type memory cells are arranged in a matrix.

2. Related Art

The virtually static random access memory (VSRAM) is known as a semiconductor memory device that is developed so as to have both advantages of the dynamic random access memory (DRAM) and the static random access memory (SRAM). The VSRAM, which may also be referred to as the pseudo static random access memory (PSRAM), has a memory cell array including the same dynamic type memory cells as the DRAM and incorporates a refresh timer with which refresh operations are carried out internally. An external device connected to the VSRAM (e.g. CPU) can therefore access the VSRAM (read/write data) without regard to refresh operations.

Some VSRAMs have, instead of typical random access mode, burst mode in which access is directed with one address specified, thereby enabling consecutive accesses to the specified address at the beginning and to the addresses following the specified address. (See the following example of related art.)

An example of related art is 32 Mb and 64 Mb Burst CellularRAM. DataSheet. [online]. Micron Technology Inc., 2004, retrieved on Aug. 20, 2004 from the Internet.

In the burst mode of the conventional VSRAM as noted above, if the switch of a select word line occurs during consecutive access, the VSRAM cannot perform access at the same access speed as in the case where the switch of a select word does not occur, and requires a wait time. Therefore, the conventional VSRAM employs a structure m which a wait signal is output to an external device such that the external device is directed to wait for access execution. Accordingly, the conventional VSRAM cannot perform consecutive access strictly and is insufficient with regard to consecutive access.

Regarding a structure that strictly enables consecutive access, for example, in the synchronous DRAM (SDRAM) having the same dynamic type memory cell as the VSRAM, a structure is suggested. If the switch of a select word line occurs during consecutive access, consecutive access is achieved by reissuing a control command for directing access (for example, see Japanese Unexamined Patent Publication No. 2002-244920). In this structure, however, it is necessary to reissue a control command whenever the switch of a select word line occurs during consecutive access. The structure cannot therefore enable consecutive access by directing access to a single address, and is insufficient with regard to consecutive access.

### SUMMARY

An advantage of the invention is to provide a technique for enabling consecutive access strictly in burst mode in a semiconductor memory device such as a VSRAM.

According to an aspect of the invention, a semiconductor memory device includes a plurality of banks including memory cell arrays in which dynamic type memory cells are arranged in a matrix, according to an input address and an input control command in synchronization with a clock signal, the memory cell corresponding to the input address being accessed in response to the input control command; wherein the input address is set as an X address for selecting a word line in the memory cell array, a Y address for selecting a data line pair in the memory cell array, and a bank address for selecting a bank, the bank address being placed in lower bits than the X address; and wherein, in burst operations that correspond to a sequence of addresses containing the input address as a leading address and consecutively perform access corresponding to the input control command to a plurality of memory cells arranged over the plurality of banks, in order for a sequence of memory cells included in one bank among the plurality of memory cells to be accessed, a word line corresponding to the sequence of memory cells is activated while a word line corresponding to a sequence of memory cells included in another bank to be accessed subsequent to access to the sequence of memory cells included in the one bank is activated in advance, and access to the sequence of memory cells included in the one bank and access to the sequence of memory cells included in the another bank are consecutively performed in synchronization with the clock signal.

According to the above semiconductor memory device, if a value of X address changes, a value of bank address necessarily changes. Therefore, there can be provided such a structure that if a word line to be activated is switched by the change of X address, the bank of a memory cell to be accessed is necessarily switched. Thus, it can be prevented that a plurality of memory cells that are accessed consecutively by burst operations are arranged over different word lines in the same bank. In order for a sequence of memory cells included in one bank to be accessed, a word line corresponding to the sequence of memory cells is activated, while a word line corresponding to a sequence of memory cells included in another bank to be accessed subsequent to access to the sequence of memory cells included in the one bank is activated in advance. This can eliminate the wait time described in the related art, enabling consecutive access strictly.

The above semiconductor memory device may include an address counter for counting the sequence of addresses sequentially from the leading address in synchronization with the clock signal; and an X address latch for recording an X address corresponding to the sequence of memory cells included in the one bank and an X address corresponding to the sequence of memory cells included in the another bank; wherein each of the plurality of banks may have an X decoder for activating one of a plurality of word lines in the memory cell array according to an X address supplied from the X address latch, and a Y decoder for selecting at least one of a plurality of data line pairs in the memory cell array according to a Y address supplied from the address counter provided; and wherein, in the burst operations, if a bank address corresponding to the one bank is a final bank address, an X address counted up by one from the X address corresponding to the sequence of memory cells included in the one bank may be recorded to the X address latch as the X address corresponding to the sequence of memory cells included in the another bank and supplied to the X decoder provided for the another bank.

An aspect of the invention can be achieved in various forms, for example, in the forms of a semiconductor memory device, a method for controlling a semiconductor memory device, and an electronic apparatus with a semiconductor memory device, etc.

### BRIEF DESCRIPTION OF THE DRAWINGS

The invention will be described with reference to the accompanying drawings, wherein like numbers refer to like elements, and wherein:

FIG. 1 is a schematic block diagram showing the internal structure of a VSRAM 10 as an embodiment of the semiconductor memory device of the invention;

FIGS. 2A, 2B, and 2C are explanatory tables illustrating addresses accessed in burst mode;

FIG. 3 is a timing chart showing access operations when memory cells corresponding to the addresses shown in FIG. 2B are accessed in burst mode;

FIG. 4 is a timing chart showing access operations when memory cells corresponding to the addresses shown in FIG. 2C are accessed in burst mode;

FIG. 5 is a perspective view of a cellular phone as an embodiment of an electronic apparatus using a semiconductor memory device according to an embodiment of the invention; and

FIG. 6 is a block diagram showing an electric configuration of a cellular phone 700 of FIG. 5.

### DESCRIPTION OF THE EMBODIMENTS

A mode of practicing the invention will now be described on the basis of an embodiment in the following order:
A. Structure of Semiconductor Memory Device
B. Operations in Burst Mode
   B1. Outline of Access Operations
   B2. Access Operation Timing
C. Effects
D. Application Examples to Electronic Apparatus
E. Modifications
   A. Structure of Semiconductor Memory Device

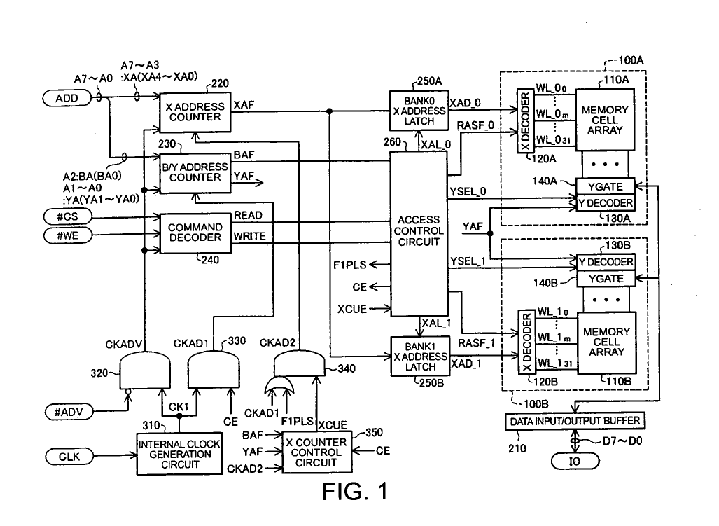

FIG. 1 is a schematic block diagram showing the internal structure of the VSRAM 10 as an embodiment of the semiconductor memory device of the invention. The VSRAM 10 is a semiconductor memory device that is accessible by following the same procedures as the normal synchronous SRAM, and an integrated circuit constructed on a single semiconductor substrate.

The VSRAM 10 has the following terminals (portions indicated by characters surrounded by solid lines in the drawing):

ADD (A0 to A7): address input terminal (8 pieces),

#CS: chip select input terminal,

#WE: write-enable input terminal,

#ADV: address valid input terminal,

IO (D0 to D7): data input/output terminal (8 pieces), and

CLK: clock input terminal.

The same reference numerals are used for terminal names and signal names in the description hereinafter. The symbol “#” added to the beginning of a terminal name (a signal name) indicates negative logic. A plurality of address input terminals ADD and a plurality of data input/output terminals IO are provided, but are illustrated in simplified shapes in FIG. 1. Other terminals such as supply terminals that are not particularly necessary for the below description are omitted.

The VSRAM 10 contains memory blocks 100A and 100B for constituting two bank memories. The VSRAM 10 also contains a data input/output buffer 210, an X address counter 220, a B/Y address counter 230, a command decoder 240, two X address latches 250A and 250B, an internal clock generation circuit 310, a load clock generation circuit 320, a B/Y count clock generation circuit 330, an X count clock generation circuit 340, and an X counter control circuit 350, as peripheral circuits for controlling accesses to the two memory blocks 100A and 100B. The VSRAM 10 contains various control circuits such as a control circuit for refresh access other than the peripheral circuits noted above, but they are not particularly necessary for description of this embodiment and therefore their figures and explanations will be omitted.

The first memory block 100A includes a memory cell array 110A corresponding to a bank 0 (hereinafter denoted as BANK0), an X decoder 120A, a Y decoder 130A, and a Y select circuit (YGATE) 140A. The second memory block 100B includes a memory cell array 110B corresponding to a bank 1 (hereinafter denoted as BANK1), an X decoder 120B, a Y decoder 130B, and a Y select circuit (YGATE) 140B.

In the first memory block 100A, the structure of the memory cell array 110A corresponding to BANK0 is the same as a memory cell array of the typical DRAM. That is, the memory cell array 110A is a memory cell array in which a plurality of one-transistor one-capacitor type (dynamic type) memory cells are arranged in a matrix. Although illustration in the figure is omitted, select terminals of memory cells arranged to the same row are connected to the same word line (WL), row by row; data input/output terminals of memory cells arranged to the same column are connected to the same data line pair, column by column. The X decoder 120A including an X driver responds to an X address signal supplied, and selects and activates a single word line among word lines (WL: WL₀ to WL₃₁) of the memory cell array 110A. The Y decoder 130A including a column driver simultaneously selects a data line pair for 1 bite (8 bits) among plural data line pairs in the memory cell array 110A by the Y select circuit 140A according to a 2-bit column address (which may be referred to as “Y address” hereinafter) supplied. The Y select circuit 140A includes a read circuit and a write circuit, enabling 1 byte data to be exchanged between the data input/output buffer 210 and the memory cell array 110A. A precharge circuit and a sense amplifier, which are not shown, are also provided in the first memory block 100A.

The memory cell array 110B, X decoder 120B, Y decoder 130B, and Y select circuit 140B in the second memory block 100B are the same as the memory cell array 110A, X decoder 120A, Y decoder 130A, and Y select circuit 140A in the first memory block 100A.

The 8-bit data input/output terminals IO (D0 to D7) are connected to input/output terminals of the data input/output buffer 210.

The dock input from the dock input terminal CLK is supplied to the internal dock generation circuit 310. The internal dock generation circuit 310 shapes the dock CLK input, and generates an internal dock CK1. The internal clock CK1 is supplied to an access control circuit 260 and serves as a reference dock for controlling access operations. The internal dock CK1 is also supplied to the load clock generation circuit 320 and the B/Y count dock generation circuit 330.

An address valid signal input from the address valid input terminal #ADV is supplied to the load clock generation circuit 320. The load dock generation circuit 320 outputs the internal dock CK1 as a load dock CKADV while the address valid signal #ADV is active. The load clock CKADV is supplied to the X address counter 220, B/Y address counter 230, and command decoder 240.

The B/Y count dock generation circuit 330 outputs the internal clock CK1 as a B/Y count clock CKAD1 while a Y select enable signal (a column enable signal) CE supplied from the access control circuit 260 is active. The B/Y count dock CKAD1 is supplied to the B/Y address counter 230.

The X count dock generation circuit 340 outputs an X count auxiliary dock F1PLS supplied from the access control circuit 260 or the B/Y count dock CKAD1 as an X count dock CKAD2 only while an X count enable signal XCUE supplied from the X counter control circuit 350 is active. The X count dock CKAD2 is supplied to the X address counter 220.

The X counter control circuit 350 outputs the X count enable signal XCUE according to a bank address signal BAF and a Y address signal YAF supplied from the B/Y address counter 230 and the Y select enable signal CE and the X count clock CKAD2 supplied from the access control circuit 260. The X count enable signal XCUE is supplied to the access control circuit 260 and the X count clock generation circuit 340.

The upper 5-bit address signal A7 to A3 among the address signals input from the 8-bit address input terminal ADD (A0 to A7) is input as the X address signal XA (XA4 to XA0) to the X address counter 220. The lower 2-bit address signal A1 to A0 is set as the Y address signal YA (YA1 to YA0), while the 1 bit address signal A2 between the X address signal XA and the Y address signal YA is set as a bank address signal BA (BA0), and both address signals are supplied to the B/Y address counter 230.

The X address counter 220 loads the upper 5-bit address signal A7 to A3 as preset data of the X addresses XA (XA4 to XA0) according to the load clock CKADV Then the 5-bit loaded preset data or 5-bit data counted up according to the X count clock CKAD2 is output as an X address signal XAF. The X address signal XAF is supplied to the X address latch 250A corresponding to BANK0 and the X address latch 250B corresponding to BANK1.

The B/Y address counter 230 loads the lower 3-bit address signal A2 to A0 as preset data of the bank address and the Y address according to the load clock CKADV Then, among the loaded 3-bit preset data or 3-bit data counted up according to the B/Y count clock CKAD1, the most significant bit is output as the bank address signal BAF, and the remaining lower 2 bits as the Y address signal YAF. The Y address signal YAF is input to the Y decoder 130A of BANK0 and the Y decoder 130B of BANK1. The bank address signal BAF is supplied to the access control circuit 260.

A chip select signal and a write enable signal input from the chip select input terminal #CS and the write enable input terminal #WE are input to the command decoder 240. The command decoder 240 loads the chip select signal #CS and the write enable signal #WE according to the load clock CKADV Then the command decoder 240 outputs a read signal READ or a write signal WRITE depending on the combination of the chip select signal #CS and write enable signal #WE that are loaded. The read signal READ and write signal WRITE are supplied to the access control circuit 260.

If performing access to BANK0 based on the bank address signal BAF supplied from the B/Y address counter 230 and the read signal READ or write signal WRITE supplied from the command decoder 240, the access control circuit 260 outputs an X address latch signal XAL_0, a WL activate signal RASF_0, and a Y select signal YSEL_0 to the X address latch 250A, X decoder 120A, and Y decoder 130A that correspond to BANK0, respectively. If performing access to BANK1, the access control circuit 260 outputs an X address latch signal XAL_1, a WL activate signal RASF_1, and a Y select signal YSEL_1 to the X address latch 250B, X decoder 120B, and Y decoder 130B that correspond to BANK1, respectively. The access control circuit 260 outputs the Y select enable signal CE and X count auxiliary clock F1PLS.

When the WL activate signal RASF_0 of BANK0 becomes active, the X decoder 120A of BANK0 selects and activates a word line WL that corresponds to the X address represented by the select X address signal XAD_0 of BANK0 supplied from the X address latch 250A of BANK0. At this time, the Y decoder 130A of BANK0 selects a data line pair that corresponds to the Y address represented by the Y address signal YAF through the Y select circuit 140A. Thus a memory cell of BANK0 is identified from the X address XA represented by the select X address signal XAD_0 of BANK0, the bank address BA represented by the bank address signal BAF, and the Y address YA represented by the Y address signal YAF, and access to the memory cell therefore becomes possible. Similarly, when the WL activate signal RASF_1 of BANK1 becomes active, the X decoder 120B of BANK1 selects a word line WL that corresponds to the X address represented by the select X address signal XAD_1 of BANK1 supplied from the X address latch 250B of BANK1, and makes it activated. At this time, the Y decoder 130B of BANK1 selects a data line pair that corresponds to the Y address represented by the Y address signal YAF through the Y select circuit 140B. Thus a memory cell of BANK1 is identified from the X address XA represented by the select X address signal XAD_1 of BANK1, the bank address BA represented by the bank address signal BAF, and the Y address YA represented by the Y address signal YAF, and access to the memory cell is thereby enabled.

B. Operations in Burst Mode

A feature of an embodiment of the invention lies in operations in burst mode. Access operations in burst mode will be described below, with a burst length BL of [8] taken as an example.

B1. Outline of Access Operations

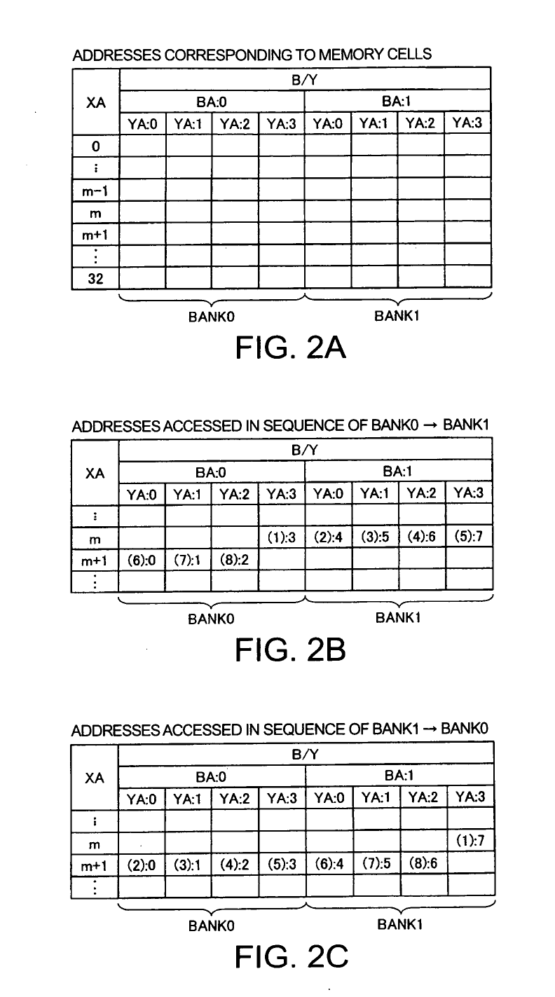

FIGS. 2A through 2C are explanatory tables illustrating addresses accessed in burst mode. Each cell of the table indicates a memory cell represented by a row that the X address XA identifies and by a column of BANK0 or BANK1 that the bank address BA and Y address YA identify.

Since the bank address BA is placed in lower bits than the X address XA and in upper bits than the Y address YA in this embodiment, there are memory cells corresponding to the same Y address in either BANK0 or BANK1 for a single X address as shown in FIG. 2A. The memory cell of BANK0 and the memory cell of BANK1 are therefore related with each other by the bank address BA.

Access operations in burst mode are generally classified into two cases as shown in FIGS. 2B and 2C. In one case, after access to the memory cell of BANK0 has been completed, the memory cell of BANK1 corresponding to the same X address as in the access to the memory cell of BANK0 is accessed. In the other case, after access to the memory cell of BANK1 has been completed, the memory cell of BANK0 corresponding to the X address incremented by one from the X address in the access to the memory cell of BANK1 is accessed.

It should be noted in the following description that, for example, an X address XA and a bank address BA may be collectively denoted as X/B addresses, a bank address BA and a Y address YA as B/Y addresses, and an X address XA and a Y address YA as X/Y addresses. An X address XA, a bank address BA, and Y address YA may also be collectively denoted as X/B/Y addresses. Also, B/Y addresses of [0/0], for example, indicate that the bank address BA is [0] and the Y address YA is [0]. X/B/Y addresses of [0/0/0] indicate that the X address is [0], the bank address BA is [0], and the Y address YA is [0].

If X/B/Y addresses at which access is initiated are [m/0/3] (m is an integer equal to or greater than 0) as shown in FIG. 2B, memory cells corresponding to eight consecutive addresses with X/B/Y addresses ranging from [m/0/3] to [m+1/0/2] will be accessed consecutively. Specifically, since the bank address BA of the address at which access is initiated is [0], BANK0 will be accessed firstly. In BANK0, since the Y address YA of the address at which access is initiated is [3], the memory cell corresponding to an X address XA of [m] and B/Y addresses of [0/3] (=[3]) will be accessed. Next, X/B/Y addresses next to the X/B/Y addresses of [m/0/3] at which access is initiated are ranging from [m/1/0] to [m/1/3]; since any bank address BA is [1], BANK1 will be accessed. In BANK1, the memory cells corresponding to an X address XA of [m] and B/V addresses ranging from [1/0] (=[4]) to [1/3] (=[7]) will be accessed sequentially. Further, the next X/B/Y addresses are ranging from [m+1/0/0] to [m+1/0/2]; since any bank address BA is [0], BANK0 will be accessed again. In BANK0, the memory cells corresponding to an X address XA of [m+1] and B/Y addresses ranging from [0/0] (=[0]) to [0/2] (=[2]) will be accessed sequentially. Thus, the memory cells corresponding to eight consecutive addresses with X/B/Y addresses ranging from [m/0/3] to [m+1/0/2] will be accessed consecutively. Incidentally, in the drawings, numerals in parentheses indicate access orders, and numerals following colon indicate values of 3-bit B/Y addresses.

Also, if X/B/Y addresses at which access is initiated are [[m/1/3] as shown in FIG. 2C, memory cells corresponding to eight consecutive addresses with X/B/Y addresses ranging from [m/1/3] to [m+1/1/2] will be accessed consecutively. Specifically, since the bank address BA of the address at which access is initiated is [1], BANK1 will be accessed firstly. Since the Y address YA is [3], in BANK1, the memory cell corresponding to an X address XA of [m] and B/Y addresses of [1/3] (=[7]) will be accessed. Next, X/B/Y addresses next to the X/B/Y addresses of [m/1/3] at which access is initiated are ranging from [m+1/0/0] to [m+1/0/3]; since any bank address BA is [0], BANK0 will be accessed. In BANK0, the memory cells corresponding to an X address XA of [m+1] and B/Y addresses ranging from [0/0] (=[0]) to [0/3] (=[3]) will be accessed sequentially. Further, the next X/B/Y addresses are ranging from [m+1/1/0] to [m+1/1/2]; since any bank address BA is [1], BANK1 will be accessed again. In BANK1, the memory cells corresponding to an X address XA of [m+1] and B/Y addresses ranging from [1/0] (=[4]) to [1/2] (=[6]) will be accessed sequentially. Thus, the memory cells corresponding to eight consecutive addresses with X/B/Y addresses ranging from [m/1/3] to [m+1/1/2] will be accessed consecutively. Incidentally, in the drawings, numerals in parentheses indicate access orders, and numerals following colon indicate values of 3-bit B/Y addresses.

As described above, since the bank address BA is placed in lower bits than the X address XA, a value of the bank address BA necessarily changes if a value of the X address XA changes. Therefore, there is provided such a structure that the bank of a memory cell that is accessed is necessarily switched if the word line that is activated by the X address XA is switched.

B2. Access Operation Timing

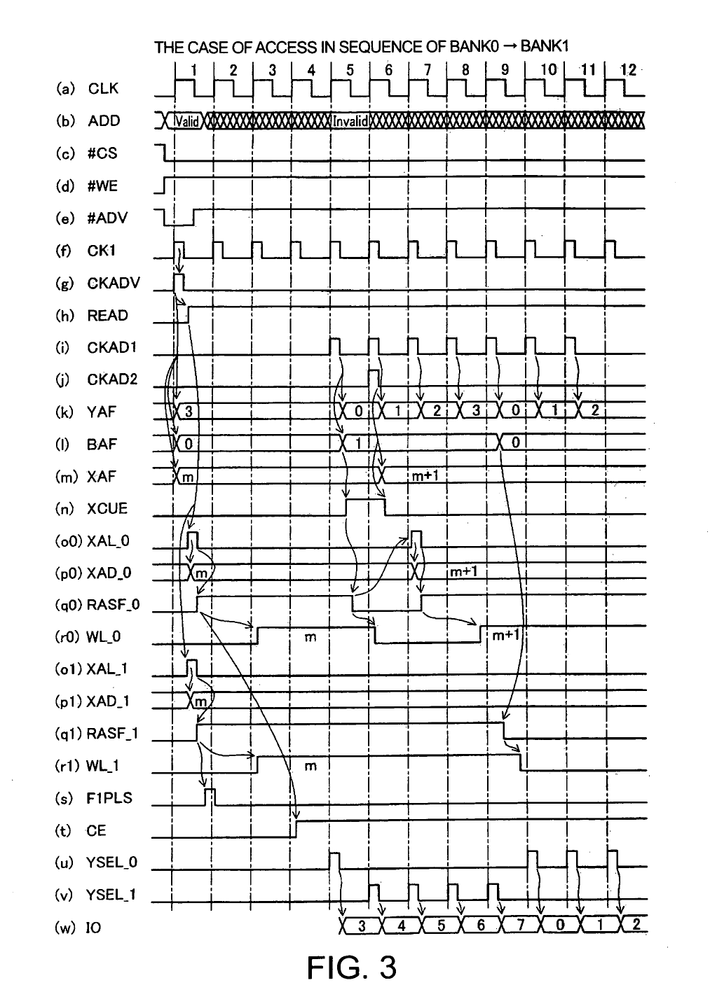

FIG. 3 is a timing chart showing access operations when memory cells corresponding to the addresses shown in FIG. 2B are accessed in burst mode. The timing chart is based on the assumption that the chip select signal #CS (FIG. 3(c)) changes to being active (L level) and the write enable signal #WE (FIG. 3(d)) also changes to being inactive (H level), and therefore read access in burst mode is required immediately before the beginning of the first cycle of the clock CLK (FIG. 3(a)). It is also assumed that the address valid signal #ADV (FIG. 3(e)) changes to being active in synchronization with the change of the chip select signal #CS to being active, and changes to being inactive in response to the falling edge of the clock CLK in the first cycle.

The read access in burst mode of this embodiment is performed in twelve cycles of the clock CLK from the first cycle through twelfth cycle as will be described below.

In the first cycle, a pulse signal of the internal clock CK1 is output as the load clock CKADV (FIG. 3(g)) in the period in which the address valid signal #ADV is active.

Then, according to a pulse signal that occurs on the load clock CKADV, the upper 5 bits of the address signal ADD (A7 to A0) (FIG. 3(b)) are loaded to the X address counter 220 (FIG. 1) as X address XA (XA4 to XA0), and are output as the 5-bit X address signal XAF (XAF4 to XAF0) (FIG. 3(m)). The lower 3 bits of the address signal ADD are loaded as bank address BA (BA0) and Y address YA (YA1 to YA0) to the B/Y address counter 230 (FIG. 1). The most significant bit of them is output as the bank address BAF (BAF0) (FIG. 3(l)) and the remaining lower 2 bits of them are output as the Y address signal YAF (YAF1 to YAF0) (FIG. 3(k)).

According to a pulse signal that occurs on the load clock CKADV, the chip select signal #CS and write enable signal #WE are also loaded to the command decoder 240 (FIG. 1). At this time, since the chip select signal #CS is active (L level) and the write enable signal #WE is inactive (H level), a command that is directed from an external device is determined to be read access and therefore the read signal READ (FIG. 3(b)) is set to be active (H level). If the write enable signal #WE is active (L level), a command that is directed is determined to be write access and therefore the write signal WRITE not shown is set to be active (H level).

When the read signal READ changes to being active, a one-shot pulse signal occurs on the X address latch signal XAL_0 (FIG. 3(o0)) for the X address latch 250A (FIG. 1) corresponding to BANK0 and on the X address latch signal XAL_1 (FIG. 3(o1)) for the X address latch 250B (FIG. 1) corresponding to BANK1 by the access control circuit 260 (FIG. 1).

In the X address latch 250A corresponding to BANK0 and the X address latch 250B corresponding to BANK1, the X address signal XAF input from the X address counter 220 (FIG. 1) is latched with the pulse signal that occurs on the X address latch signal XAL_0 and the X address latch signal XAL_1, which respectively correspond to the X address latch 250A and the X address latch 250B. Data latched in the X address latch 250A corresponding to BANK0 and the X address latch 250B corresponding to BANK1 is output as the select X address signal XAD_0 of BANK0 (FIG. 3(p0)) and the select X address signal XAD_1 of BANK1 (FIG. 3(p1)). In the first cycle, since the X address XA that is represented by the X address signal XAF output from the X address counter 220 is [m], the select X addresses that are output as the select X address signal XAD_0 of BANK0 and the select X address signal XAD_1 of BANK1 become [m].

Then, according to the filling edge timing of the X address latch signal XAL_0 of BANK0, the WL activate signal RASF_of BANK0 (FIG. 3(q0)) is made active by the access control circuit 260. Similarly, according to the falling edge timing of the X address latch signal XAL_1 of BANK1, the WL activate signal RASF_1 of BANK1 (FIG. 3(q1)) is made active by the access control circuit 260, and also, according to the rising edge timing of the WL activate signal RASF_1, a one-shot pulse signal occurs on the X count auxiliary clock F1PLS. However, the X count auxiliary clock F1PLS is used only when an X count enable signal XCUE (FIG. 3(n)) is active, and therefore the X count auxiliary clock F1PLS is not particularly necessary in this embodiment.

When the WL activate signal RASF_0 of BANK0 and WL activate signal RASF_1 of BANK1 become active, a word line WL_0 corresponding to the select X address represented by the select X address signal XAD_0 of BANK0 (FIG. 3(r0)) and a word line WL_1 corresponding to the select X address represented by the select X address signal XAD_1 of BANK1 (FIG. 3(r1)) are accordingly activated. After the corresponding word lines WL_0 and WL_1 are activated, the Y select enable signal CE (FIG. 3(t)) is made active (H level) by the access control circuit 260.

The corresponding word line WL_0 of BANK0 and word line WL_1 of BANK1, however, are not activated immediately after the WL activate signal RASF_0 of BANK0 and WL activate signal RASF_1 of BANK1 change to being active, but are activated after an elapse of delay time caused by a circuit that operates for activating the word lines. In the case shown in the drawing, the word lines are activated in the third cycle.

Also, the Y select enable signal CE is not made active (H level) immediately after the WL activate signal RASF_0 of BANK0 and WL activate signal RASF_1 of BANK1 change to being active, but are set to become active in consideration of the delay time that is required for the corresponding word line WL_0 of BANK0 and corresponding word line WL_1 of BANK1 to be activated. In the case of the drawing, the Y select enable signal CE is set to become active in the fourth cycle in consideration of the word line WL_0 of BANK0 and word line WL_1 of BANK1 being activated in the third cycle.

When the Y select enable signal CE changes to being active, a clock for sequentially counting up B/Y addresses represented by the bank address signal BAF and the Y address signal YAF that are output from the B/Y address counter 230 (FIG. 1) is output to the B/Y count clock CKAD1 (FIG. 3(i)) based on the internal clock CK1. In the case of the drawing, a pulse signal that occurs with the same timing as the internal clock CK1 is output as the B/Y count clock CKAD1 in seven cycles from the fifth to the eleventh cycle.

The B/Y addresses are counted up sequentially from [0/3] (=[3]) with the falling edge timing of the B/Y count clock CKAD1 in each cycle. Specifically, the B/Y addresses are [1/0] (=[4]) in the fifth cycle, [1/1] (=[5]) in the sixth cycle, [1/2] (=[6]) in the seventh cycle, and [1/3] (=[7]) in the eighth cycle. The B/Y addresses return to [0/0] (=[0]) in the ninth cycle, and are [0/1] (=[1]) in the tenth cycle and [0/2] (=[2]) in the eleventh cycle.

At this point, when the bank address BA changes to [1] with the falling edge timing of the B/Y count clock CKAD1 in the fifth cycle, the X count enable signal XCUE (FIG. 3(n)) is made active (H level) by the X counter control circuit 350. When the X count enable signal XCUE changes to being active, the WL activate signal RASF_0 of BANK0 is made inactive by the access control circuit 260. Thus, the activated word line WL_0 of BANK0 is inactivated.

Then, the X count enable signal XCUE is initially active in the sixth cycle. According to this, the internal clock CK1 is output as the X count clock CKAD2 (FIG. 3(j)). At this time, the X address XA that is represented by the X address signal XAF output from the X address counter 220 (FIG. 1) is countered up to be [m+1] with the falling edge timing of the X count clock CKAD2. Also, the X count enable signal XCUE is returned to be inactive.

On the X address latch signal XAL_0 of BANK0, after a certain period of time in consideration of delay time from change of the X count enable signal XCUE to being active to inactivation of the activated word line WL_0 of BANK0 and precharge time has passed, in the seventh cycle in this case, a one-shot pulse signal is output again. At this time, the X address latch 250A of BANK0 latches the X address signal XAF according to the X address latch signal XAL_0 of BANK0, and outputs it as the select X address signal XAD_0 of BANK0 (FIG. 3(p0)). In the case of the drawing, since the X address XA that is represented by the X address signal XAF output from the X address counter 220 becomes [n+1] in the sixth cycle, the select X address that is represented by the select X address signal XAD_0 of BANK0 becomes [m+1]. According to the falling edge timing of the X address latch signal XAL_0 of BANK0, the WL activate signal RASF_0 of BANK0 is made active again.

When the WL activate signal RASF_0 of BANK0 changes to being active again, the word line WL_0 corresponding to the select X address of the X address signal XAD_0 of BANK0 is accordingly activated after delay time of the circuit that operates for activating a word line has elapsed. In this case, the corresponding word line WL_0 of BANK0 is activated before the ninth cycle begins.

In the ninth cycle, when the bank address BA changes to [0] with the falling edge timing of the B/Y count clock CKAD1, the WL activate signal RASF_1 of BANK1 is accordingly made inactive. The activated word line WL_1 of BANK1 is inactivated.

When the Y select enable signal CE changes to being active in the fourth cycle, a pulse signal that occurs with substantially the same timing as the internal clock CK1 based on the internal clock CK1 is output on the Y select signal YSEL_0 of BANK0 (FIG. 3(u)) or the Y select signal YSEL_1 of BANK1 (FIG. 3(v)), according to the change of the bank address BA represented by the bank address signal BAF. In the case of the drawing, in eight cycles from the fifth to the twelfth cycle, since the bank address BA is “1” in the sixth to ninth cycles, a pulse signal for four cycles occurs on the Y select signal YSEL_1 of BANK1, while since the bank address BA is “0” in four cycles consisting of the fifth cycle and the tenth to twelfth cycles, a pulse signal for four cycles occurs on the Y select signal YSEL_0 of BANK0.

At this point, the select X address represented by the select X address signal XAD_0 of BANK0 is [m], which is the same as the X address XA that is set, and the word line WL_0 corresponding to this is activated in the fifth cycle. The memory cell of BANK0 that corresponds to the X address XA of [m] and the B/Y addresses of [0/3](=[3]) is therefore accessed according to the Y select signal YSEL_0 of BANK0, and the data is output from the data input/output terminal IO (FIG. 3(w)). In the sixth to ninth cycles, the select X address represented by the select X address signal XAD_1 of BANK1 is [m], which is the same as the X address XA that is set, and the word line WL_1 corresponding to this is activated. The memory cells of BANK1 that correspond to the X address XA of [m] and the four B/Y addresses of [1/0] (=[4]), [1/1] (=[5]), [1/2] (=[6]), and [1/3] (=[7]) are therefore accessed sequentially according to the Y select signal YSEL_1 of BANK1, and the data is output from the data input/output terminal IO. Further in the tenth to twelfth cycles, the select X address represented by the select X address signal XAD_0 of BANK0 is [m+1], which is obtained by incrementing the X address XA set by one, and the word line WL_0 corresponding to this is activated. The memory cells of BANK0 that correspond to the three B/Y addresses of [0/0] (=[0]), [0/1] (=[1]), and [0/2] (=[2]) are therefore accessed sequentially according to the Y select signal YSEL_0 of BANK0, and the data is output from the data input/output terminal IO.

As described above, if memory cells corresponding to addresses shown in FIG. 2B are accessed in burst mode, the access operations are performed with the operation timing shown in FIG. 3.

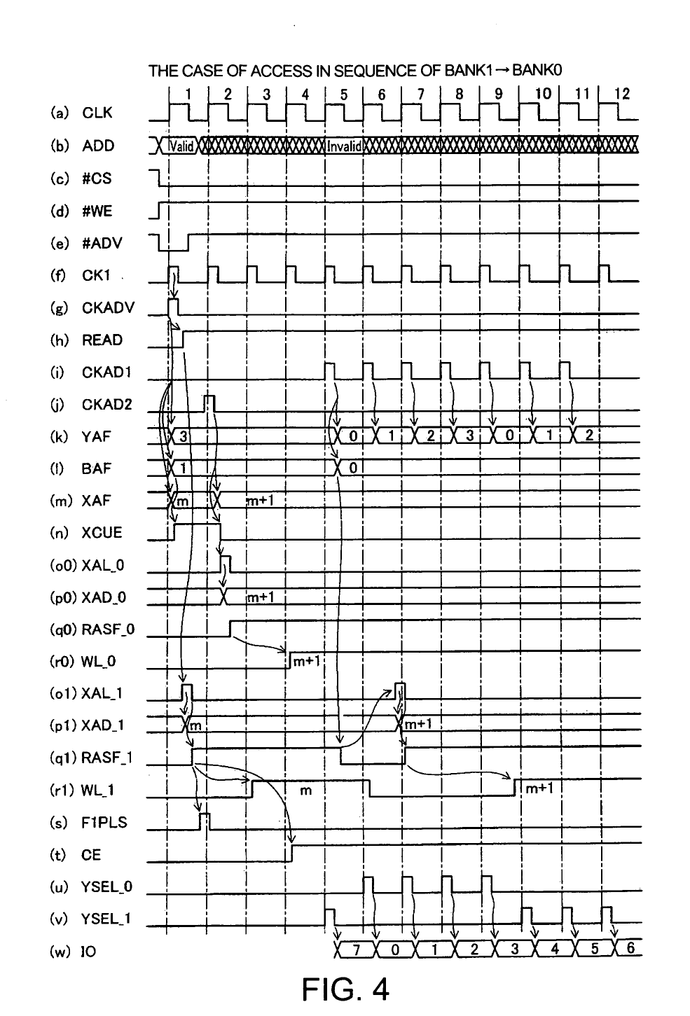

FIG. 4 is a timing chart showing access operations when memory cells corresponding to the addresses shown in FIG. 2C are accessed in burst mode. The timing chart is based on the assumption that the chip select signal #CS (FIG. 4(c)) changes to being active (L level) and the write enable signal #WE (FIG. 4(d)) also changes to being inactive (H level), and therefore read access in burst mode is required immediately before the first cycle of the clock CLK begins (FIG. 4(a)). It is also assumed that the address valid signal #ADV (FIG. 4(e)) changes to being active in synchronization with the change of the chip select signal #CS to being active, and changes to being inactive in response to the falling edge of the clock CLK in the first cycle.

The read access in burst mode of this embodiment is also performed in twelve cycles of the clock CLK from the first cycle through twelfth cycle as will be described below.

In the first cycle, a pulse signal of the internal clock CK1 is output as the load clock CKADV (FIG. 4(g)) in the period in which the address valid signal #ADV is active.

Then, according to a pulse signal that occurs on the load clock CKADV, the upper 5 bits of the address signal ADD (A7 to A0) (FIG. 4(b)) are loaded to the X address counter 220 (FIG. 1) as X address XA (XA4 to XA0), and are output as the 5-bit X address signal XAF (XAF4 to XAF0) (FIG. 4(m)). The lower 3 bits of the address signal ADD are loaded as bank address BA (BA0) and Y address YA (YA1 to YA0) to the B/Y address counter 230 (FIG. 1). The most significant bit of them is output as the bank address BAF (BAF0) (FIG. 4(l)) and the remaining lower 2 bits of them are output as the Y address signal YAF (YAF1 to YAF0) (FIG. 4(k)).

According to a pulse signal that occurs on the load clock CKADV, the chip select signal #CS and write enable signal #WE are also loaded to the command decoder 240 (FIG. 1). At this time, since the chip select signal #CS is active (L level) and the write enable signal #WE is inactive (H level), a command directed from an external device is determined to be read access and therefore the read signal READ (FIG. 4(h)) is set to be active (H level).

When the read signal READ changes to being active, a one-shot pulse signal occurs on the X address latch signal XAL_1 (FIG. 4(o1)) for the X address latch 250B (FIG. 1) corresponding to BANK1 by the access control circuit 260 (FIG. 1).

In the X address latch 250B corresponding to BANK1, the X address signal XAF input from the X address counter 220 (FIG. 1) is latched with the pulse signal that occurs on the corresponding X address latch signal XAL_1 and is output as the select X address signal XAD_1 of BANK1 (FIG. 4(p1)). In the first cycle, since the X address XA that is represented by the X address signal XAF output from the X address counter 220 is [m], the select X address output as the select X address signal XAD_1 of BANK1 becomes [m].

Then, according to the falling edge timing of the X address latch signal XAL_1 of BANK1, the WL activate signal RASF_1 of BANK1 (FIG. 4(q1)) is made active by the access control circuit 260, and also, according to the rising edge timing of the WL activate signal RASF_1, a one-shot pulse signal occurs on the X count auxiliary clock F1PLS.

When the WL activate signal RASF_1 of BANK1 becomes active, the word line WL_1 (FIG. 4(r1)) corresponding to the select X address represented by the select X address signal XAD_1 of BANK1 is accordingly activated. After the corresponding word line WL_1 is activated, the Y select enable signal CE (FIG. 4(t)) is made active (H level) by the access control circuit 260. The corresponding word line WL_1 of BANK1, however, is not activated in the first cycle in which the WL activate signal RASF_1 of BANK1 changes to being active, but is activated after an elapse of delay time caused by a circuit that operates for activating the word lines. In the case shown in the drawing, the word lines are activated in the third cycle, and the Y select enable signal CE is activated in the fourth cycle.

In the timing chart shown in FIG. 3, a one-shot pulse signal occurs on the X address latch signal XAL_0 (FIG. 3(o0)) corresponding to BANK0 for the X address latch 250A (FIG. 1) with the timing of change of the read signal READ to being active. However, in this case, on the X address latch signal XAL_0 (FIG. 4(o0)) corresponding to BANK0 for the X address latch 250A, a one-shot pulse signal occurs not with the timing of change of the read signal READ to being active but with the timing that will be described below.

Since the bank address BA that is output as the bank address signal BAF is changed to [1] in the first cycle, the X count enable signal XCUE (FIG. 4(n)) is accordingly made active (H level) by the X counter control circuit 350 (FIG. 1). If the X count enable signal XCUE is active, a pulse signal does not occur on the X address latch signal XAL_0 of BANK0. However, a one-shot pulse signal that occurs on the X count auxiliary clock F1PLS is output as the X count clock CKAD2 (FIG. 4(j)). Accordingly, the X address XA represented by the X address signal XAF is counted up to be [m+1] with the falling edge timing of the X count clock CKAD2 that occurs by the X count auxiliary clock F1PLS. The X count enable signal XCUE is returned to be inactive.

When the X count enable signal XCUE changes to being inactive, a one-shot pulse signal occurs on the X address latch signal XAL_0 of BANK0 by the access control circuit 260. In the X address latch 250A corresponding to BANK0, the X address signal XAF that is input from the X address counter 220 is latched with a pulse signal that occurs on the corresponding X address latch signal XAL_0, and is output as the select X address signal XAD_0 of BANK0 (FIG. 4(p0)). Since the X address XA that is represented by the X address signal XAF output from the X address counter 220 has changed to [m+1] immediately before a one-shot pulse signal occurs on the select X address signal XAD_0 of BANK0 in the second cycle, the select X address represented by the select X address signal XAD_0 of BANK0 becomes [m+1].

Then, according to the falling edge timing of the X address latch signal XAL_0 of BANK0, the WL activate signal RASF_0 of BANK0 (FIG. 4(q0)) is made active by the access control circuit 260.

When the WL activate signal RASF_0 of BANK0 is made active, the word line WL_0 (FIG. 4(r0)) corresponding to the select X address signal XAD_0 of BANK0 is accordingly activated. The corresponding word line WL_0 of BANK0, however, is not activated immediately after the WL activate signal RASF_0 of BANK0 changes to being active, but is activated after an elapse of delay time caused by a circuit that operates for activating the word lines, and the like. In the case shown in the drawing, the word lines are activated in the fourth cycle.

When the Y select enable signal CE changes to being active, a clock for sequentially counting up B/Y addresses represented by the bank address signal BAF and the Y address signal YAF that are output from the B/Y address counter (FIG. 1) is output to the B/Y count clock CKAD1 (FIG. 4(i)) based on the internal clock CK1. In the case of the drawing, a pulse signal that occurs with the same timing as the internal clock CK1 is output as the B/Y count clock CKAD1 in seven cycles from the fifth to the eleventh cycle.

The B/Y addresses are counted up sequentially from [1/3] (=[7]) with the falling edge timing of the B/Y count clock CKAD1 in each cycle. Specifically, the B/Y addresses return to [0/0] (=[0]) in the fifth cycle, and are [0/1] (=[1]) in the sixth cycle, [0/2] (=[2]) in the seventh cycle, [0/3] (=[3]) in the eighth cycle, [1/0] (=[4]) in the ninth cycle, [1/1] (=[5]) in the tenth cycle, and [1/2] (=[6]) in the eleventh cycle.

At this point, when the bank address BA changes to [0] with the falling edge timing of the B/Y count clock CKAD1 in the fifth cycle, the WL activate signal RASF_1 of BANK1 is made inactive by the access control circuit 260. Thus, the activated word line WL_1 of BANK1 is inactivated.

Then, on the X address latch signal XAL_1 of BANK1, after a certain period of time in consideration of delay time from change of the WL activate signal RASF_1 of BANK1 to being inactive to inactivation of the activated word line WL_1 of BANK1 and precharge time has passed, immediately before the seventh cycle in this case, a one-shot pulse signal is output again. At this time, the X address latch 250B of BANK1 latches the X address signal XAF according to the X address latch signal XAL_1 of BANK1, and outputs it as the select X address signal XAD_1 of BANK1 (FIG. 4(p0)). In the case of the drawing, since the X address XA represented by the X address signal XAF that is output from the X address counter 220 becomes [m+1] in the second cycle, the select X address represented by the select X address signal XAD_1 of BANK1 is also [m+1]. According to the falling edge timing of the X address latch signal XAL_1 of BANK1, the WL activate signal RASF_1 of BANK1 becomes active again.

When the WL activate signal RASF_1 of BANK1 changes to being active again, the word line WL_1 corresponding to the select X address of the X address signal XAD_1 of BANK1 is accordingly activated after delay time of the circuit operations for activating a word line has elapsed. In this case, the corresponding word line WL_1 of BANK1 is activated before the ninth cycle begins.

When the Y select enable signal CE changes to being active in the fourth cycle, pulse signals that occur with substantially the same timing as the internal clock CK1 based on the internal clock CK1 are output on the Y select signal YSEL_0 of BANK0 (FIG. 4(u)) or the Y select signal YSEL_1 of BANK1 (FIG. 4(v)), according to the change of the bank address BA represented by the bank address signal BAF In the case of the drawing, in eight cycles from the fifth to the twelfth cycle, since the bank address BAF is “0” in the sixth to ninth cycles, a pulse signal for four cycles occurs on the Y select signal YSEL_0 of BANK0, while since the bank address BAF is “1” in four cycles consisting of the fifth cycle and the tenth to twelfth cycles, a pulse signal for four cycles occurs on the Y select signal YSEL_1 of BANK1.

At this point, the select X address represented by the select X address signal XAD_1 of BANK1 is [m], which is the same as the X address XA that is set, and the word line WL_1 corresponding to this is activated in the fifth cycle. The memory cell of BANK1 that corresponds to the X address XA of [m] and the B/Y addresses of [1/3](=[7]) is therefore accessed according to the Y select signal YSEL_1 of BANK1, and the data is output from the data input/output terminal 10 (FIG. 4(w)). In the sixth to ninth cycles, the select X address represented by the select X address signal XAD_0 of BANK0 is [m], which is the same as the X address XA that is set, and the word line WL_0 corresponding to this is activated. The memory cells of BANK0 that correspond to the X address XA of [m+1] and the four B/Y addresses of [0/0] (=[0]), [0/1] (=[1]), [0/2] (=[2]), and [0/3] (=[3]) are therefore accessed sequentially according to the Y select signal YSEL_0 of BANK0, and the data is output from the data input/output terminal IO. Further in the tenth to twelfth cycles, the select X address represented by the select X address signal XAD_1 of BANK1 is [m+1], which is obtained by incrementing the X address XA set by one, and the word line WL_1 corresponding to this is activated. The memory cells of BANK1 that correspond to the three B/Y addresses of [1/0] (=[4]), [1/1] (=[5]), and [1/2] (=[6]) are therefore accessed sequentially according to the Y select signal YSEL_1 of BANK1, and the data is output from the data input/output terminal IO.

As described above, if memory cells corresponding to addresses shown in FIG. 2C are accessed in burst mode, the access operations are performed with the operation timing shown in FIG. 4.

As shown in FIGS. 3 and 4, memory cells corresponding to eight consecutive addresses can be accessed consecutively in sequence as access operations in burst mode either in the case where memory cells of BANK1 corresponding to the same X address as the X address in access to memory cells of BANK0 are accessed after access to memory cells of BANK0 has been completed or in the case where memory cells of BANK0 corresponding to the X address that is obtained by incrementing the X address in access to memory cells of BANK1 by one are accessed after access to memory cells of BANK1 has been completed.

C. Effects

In the semiconductor memory device (the VSRAM 10) of the above embodiment, since the bank address BA is placed in lower bits than the X address XA, a value of the bank address BA necessarily changes if a value of the X address XA changes. Therefore, there is provided such a structure that if the word line that is activated by the X address XA is switched, the bank of a memory cell that is accessed is necessarily switched. Thus, it can be prevented that a plurality of memory cells that are accessed consecutively in burst mode are arranged over different word lines in the same bank.

When a word line in one bank is activated and access is being performed, a word line corresponding to a memory cell to be next accessed is activated in advance in the other bank, and thus access to the other bank subsequent to access to one bank can be performed consecutively.

Accordingly, it is possible to eliminate the need for outputting a WAIT signal as in a conventional manner, and strictly consecutive access in burst mode can be enabled. Directing a control command to the access start address in burst mode can also enable consecutive access, and therefore access control from outside is easy.

D. Application Examples to Electronic Apparatus

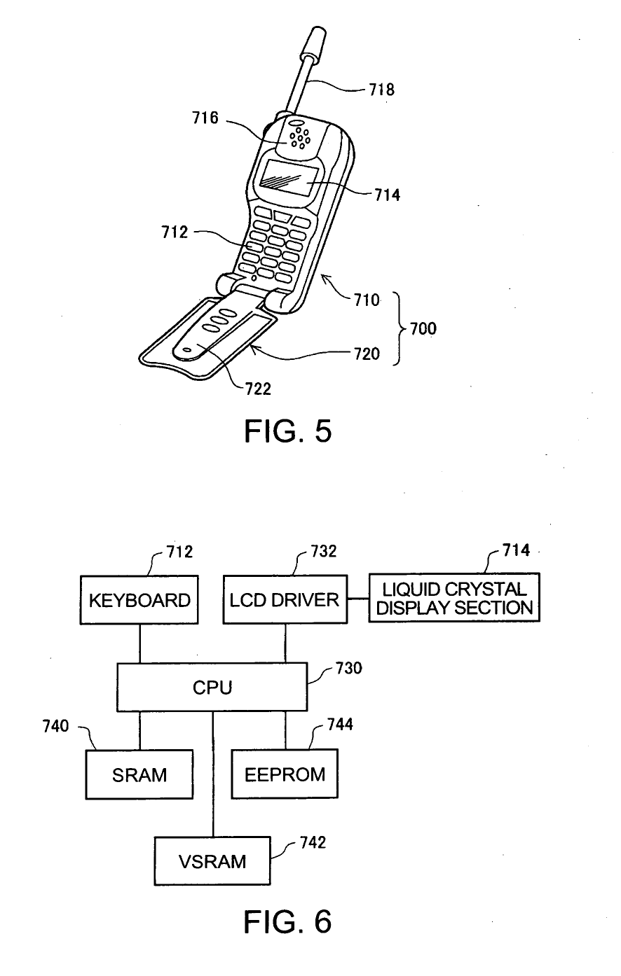

FIG. 5 is a perspective view of a cellular phone as an embodiment of an electronic apparatus using a semiconductor memory device according to an embodiment of the invention. This cellular phone 700 includes a main body 710 and a cover 720. A keyboard 712, a liquid crystal display section 714, a receiver 716, and a main body antenna 718 are provided in the main body 710. A mouthpiece 722 is provided in the cover 720.

FIG. 6 is a block diagram showing an electric configuration of the cellular phone 700 of FIG. 5. The keyboard 712, an LCD driver 732 for driving the liquid crystal display section 714, a SRAM 740, a VSRAM 742, and an EEPROM 744 are connected to the CPU 730 through bus lines.

The SRAM 740 is used, for example, as a high speed cashe memory. The VSRAM 742 is utilized, for example, as a working memory for image processing. As the VSRAM 742 (referred to as a pseudo SRAM or a virtual SRAM), the VSRAM 10 described above can be employed. The EEPROM 744 is utilized for storing various types of setting values of the cellular phone 700.

When operations of the cellular phone 700 are temporarily stopped, the VSRAM 742 can be kept in a state of standby. Thus, the VSRAM 742 automatically refreshes its inside, and therefore it is possible to maintain the data in the VSRAM 742 without losing it. In particular, the VSRAM 10 of the embodiment described above can have a relatively mass structure and therefore has an advantage of being able to keep on maintaining mass data such as image data for a long time. The VSRAM 10 of the embodiment described above need not be conscious of refresh operations, and therefore also has an advantage of being able to be used in a similar way to an SRAM. Further, the VSRAM 10 of the embodiment described above can perform consecutive access at high speed in burst mode, and therefore has an advantage of being able to consecutively access mass data such as image data at high speed.

E. Modifications

It should be understood that the invention is not restricted to the above embodiment and may be embodied in various shapes without departing from the essential characteristics thereof The following modifications, for example, may be made.

The above embodiment has described that a word line to be activated is selected not consecutively in the same bank in consecutive access in burst mode. To explain this simply, the embodiment has described the operations with a burst length BL of eight, using the case where two bank memories that are accessed with 8-bit address consisting of upper 5 bits used as X address and lower three bits, the most significant bit of which is used as the bank address and the remaining 2 bits are used as the Y address, are provided. The invention, however, is not limited to this. For example, there may be a structure in which access is performed with the address having the number of bits other than 8 bits. There may also be a structure in which the bank address is n bits (n is an integer equal to or greater than 2) and 2ⁿ bank memories, that is, plural bank memories are provided. The structure may include the X address equal to or greater than 5 bits and the Y address equal to or greater than 3 bits. In any case, the bank address should be at least placed in the bits lower than the X address. The burst length BL is also not restricted to [8] but may be set to various values as same as in conventional VSRAMs.

In the embodiment described above, the X count enable signal XCUE is made active when the bank address BA changes to [1]. This is because of the following reasons. As shown in FIG. 3, when the bank address BA changes to [1] in the fifth cycle, access to BANK1 is performed, and as a result, the activated word line of BANK0 is inactivated in four cycles from the sixth to the ninth cycle. From the tenth cycle, access to BANK0 is performed again. At this point, in order to smoothly switch the access from access to BANK1 to access to BANK0 and enable the access to BANK0, the corresponding word line of BANK0 need be activated by the tenth cycle in which access to BANK0 begins. A time interval based on consideration of operation delay time and precharge time is typically required to inactivate the word line that has been activated and to activate the next word line. Consequently, considering the requests noted above, the above embodiment has the X count enable signal XCUE changed to being active when the bank address BA changes to [1]. The possibilities are not restricted to this; the X count enable signal XCUE may be set to become active according to changes of the bank address BA and the Y address YA, so that access is smoothly switched from access to BANK1 to access to BANK0 to enable the access to BANK0.

What is claimed is:

1. A semiconductor memory device, comprising:
a plurality of banks including memory cell arrays in which dynamic type memory cells are arranged in a matrix, according to an input address and an input control command in synchronization with a clock signal, the memory cell corresponding to the input address being accessed in response to the input control command;
wherein the input address is set as an X address for selecting a word line in the memory cell array, a Y address for selecting a data line pair in the memory cell array, and a bank address for selecting a bank, the bank address being placed in lower bits than the X address; and
wherein, in burst operations that correspond to a sequence of addresses containing the input address as a leading address and consecutively perform access corresponding to the input control command to a plurality of memory cells arranged over the plurality of banks, in order for a sequence of memory cells included in one bank among the plurality of memory cells to be accessed, a word line corresponding to the sequence of memory cells is activated while a word line corresponding to a sequence of memory cells included in another bank to be accessed subsequent to access to the sequence of memory cells included in the one bank is activated in advance, and access to the sequence of memory cells included in the one bank and access to the sequence of memory cells included in the another bank are consecutively performed in synchronization with the clock signal.

2. The semiconductor memory device according to claim 1, the device further comprising:
an address counter for counting the sequence of addresses sequentially from the leading address in synchronization with the clock signal; and
an X address latch for recording an X address corresponding to the sequence of memory cells included in the one bank and an X address corresponding to the sequence of memory cells included in the another bank;
wherein each of the plurality of banks has an X decoder for activating one of a plurality of word lines in the memory cell array according to an X address supplied from the X address latch, and a Y decoder for selecting at least one of a plurality of data line pairs in the memory cell array according to a Y address supplied from the address counter provided; and
wherein, in the burst operations, if a bank address corresponding to the one bank is a final bank address, an X address counted up by one from the X address corresponding to the sequence of memory cells included in the one bank is recorded to the X address latch as the X address corresponding to the sequence of memory cells included in the another bank and supplied to the X decoder provided for the another bank.

3. An electronic apparatus, comprising: the semiconductor memory device according to claim 1.

4. A semiconductor memory device, comprising:
a plurality of banks including memory cell arrays in which dynamic type memory cells are arranged in a matrix, according to an input address and an input control command in synchronization with a clock signal the memory cell corresponding to the input address being accessed in response to the input control command;
wherein the input address is set as an X address for selecting a word line m the memory cell array, a Y address for selecting a data line pair in the memory cell array, and a bank address for selecting a bank, the bank address being placed in lower bits than the X address.

5. The semiconductor memory device according to claim 4, the Y address being placed in lower bits than the bank address.

6. The semiconductor memory device according to claim 4, in burst operations that correspond to a sequence of addresses containing the input address as a leading address and consecutively perform access corresponding to the input control command to a plurality of memory cells arranged over the plurality of banks,
after access to the memory cell of one of the banks has been completed, the memory cell of another of the banks corresponding to the same X address as in the access to the memory cell of the one of the banks is accessed.

7. The semiconductor memory device according to claim 6,
after access to the memory cell of the another of the banks has been completed, the memory cell of the one of the banks corresponding to the X address incremented by one from the X address in the access to the memory cell of the another of the banks is accessed.

8. The semiconductor memory device according to claim 4, in burst operations that correspond to a sequence of addresses containing the input address as a leading address and consecutively perform access corresponding to the input control command to a plurality of memory cells arranged over the plurality of banks,
after access to the memory cell of one of the banks has been completed, the memory cell of another of the banks corresponding to the X address incremented by one from the X address in the access to the memory cell of the one of the banks is accessed.

9. The semiconductor memory device according to claim 4, if a value of the X address is changes, the bank of the memory cell that is accessed is switched.
